(19) United States
(12) Patent Application Publication
(10) Pub. No.: US 2025/0293096 A1
(43) Pub. Date: Sep. 18, 2025

(54) DISPLAY PANEL AND FABRICATION METHOD THEREOF

(71) Applicant: AUO Corporation, Hsinchu (TW)

(72) Inventors: Ssu-Hsien Chih, Hsinchu (TW); Yi-Fu Ou, Hsinchu (TW)

(73) Assignee: AUO Corporation, Hsinchu (TW)

(21) Appl. No.: 18/655,343

(22) Filed: May 6, 2024

(30) Foreign Application Priority Data
Mar. 13, 2024 (TW) 113109305

(51) Int. Cl. H01L 21/66; H01L 33/00; H10K 71/00

(52) U.S. Cl. CPC H01L 22/22; H10H 20/01; H10K 71/861

(57) ABSTRACT

Disclosed is a display panel including a substrate, multiple first bonding pads, multiple repair pads, a pixel array, multiple first data lines, multiple transfer lines, multiple repair signal lines, and an isolation layer. The substrate has a bonding pad area, a repair area, and a pixel array area. The repair area is located between the bonding pad area and the pixel array area. The first data lines extend from the bonding pad area to the pixel array area, and the first data lines electrically connect the first bonding pads to the pixel array respectively. The transfer lines are located over the repair area and across the first data lines. The repair signal lines extend from the bonding pad area to the repair area and are electrically connected to the repair pads respectively. The isolation layer is located between the transfer lines and the repair signal lines.

### CROSS-REFERENCE TO RELATED APPLICATION

This application claims the priority benefit of Taiwan application serial no. 113109305, filed on Mar. 13, 2024. The entirety of the above-mentioned patent application is hereby incorporated by reference herein and made a part of this specification.

### BACKGROUND

### Technical Field

The disclosure relates to a display panel and a fabrication method thereof.

### Description of Related Art

To fabricate a high resolution display panel, it is necessary to dispose signal lines very densely among the pixel structures of the display panel. Due to the close proximity of the signal lines, problems concerning short circuits between adjacent signal lines easily occur. In order to repair the short-circuited signal lines, a repair process must be performed on the display panel. However, how to reduce challenges in the repair process and improve the yield of the repair process is a topic that many manufacturers are devoted to.

### SUMMARY

The disclosure provides a display panel and a fabrication method thereof, and solves problems concerning short circuits or open circuits of data lines by repairing signal lines and performing a repair process.

At least one embodiment of the disclosure provides a display panel including a substrate, multiple first bonding pads, multiple repair pads, a pixel array, multiple first data lines, multiple transfer lines, multiple repair signal lines, and an isolation layer. The substrate has a bonding pad area, a repair area, and a pixel array area. The repair area is located between the bonding pad area and the pixel array area. The first bonding pads and the repair pads are located over the bonding pad area. The pixel array is located over the pixel array area. The first data lines extend from the bonding pad area to the pixel array area, and the first data lines electrically connect the first bonding pads to the pixel array respectively. The transfer lines are located over the repair area and across the first data lines. The repair signal lines extend from the bonding pad area to the repair area and are electrically connected to the repair pads respectively. An end of each of the repair signal lines is located over the repair area. The isolation layer is located between the transfer lines and the repair signal lines.

At least one embodiment of the disclosure provides a fabrication method of a display panel, which includes the following steps. A pixel array substrate is provided. The pixel array substrate includes a substrate, multiple first bonding pads, a second bonding pad, multiple repair pads, a pixel array, multiple first data lines, a second data line, multiple repair signal lines, and an isolation layer. The substrate has a bonding pad area, a repair area, and a pixel array area. The repair area is located between the bonding pad area and the pixel array area. The first bonding pads, the second bonding pad and the repair pads are located over the bonding pad area. The pixel array is located over the pixel array area. The first data lines and the second data line extend from the bonding pad area to the pixel array area. The first data lines electrically connect the first bonding pads to the pixel array respectively. Multiple transfer lines are located over the repair area and across the first data lines and the second data line. The repair signal lines extend from the bonding pad area to the repair area and are electrically connected to the repair pads respectively. An end of each of the repair signal lines is located over the repair area. The isolation layer is located between the transfer lines and the repair signal lines. A detection procedure is performed on the pixel array substrate to detect an open circuit or a short circuit of the second data line. A welding process is performed to form a first connection point and a second connection point in the isolation layer. One of the repair signal lines is electrically connected to one of the transfer lines through the first connection point. The one of the transfer lines is electrically connected to a part of the second data line through the second connection point.

### BRIEF DESCRIPTION OF THE DRAWINGS

FIG. 1A, FIGS. 2 to 8, and FIG. 9A are top-view schematic diagrams of a fabrication method of a display panel according to an embodiment of the disclosure.

FIGS. 1B and 1C are cross-sectional schematic diagrams along Line A-A′ and Line B-B′ in FIG. 1A, respectively.

FIG. 9B is a cross-sectional schematic diagram along Line B-B′ in FIG. 9A.

FIG. 10 is a top-view schematic diagram of a display panel according to another embodiment of the disclosure.

FIGS. 11A and 11B are schematic diagrams of an arrangement of a digital signal protocol of a timing controller chip according to an embodiment of the disclosure.

FIG. 12 is a top-view schematic diagram of a display panel according to still another embodiment of the disclosure.

FIG. 13 is a flowchart of a fabrication method of a display panel in an embodiment.

### DESCRIPTION OF THE EMBODIMENTS

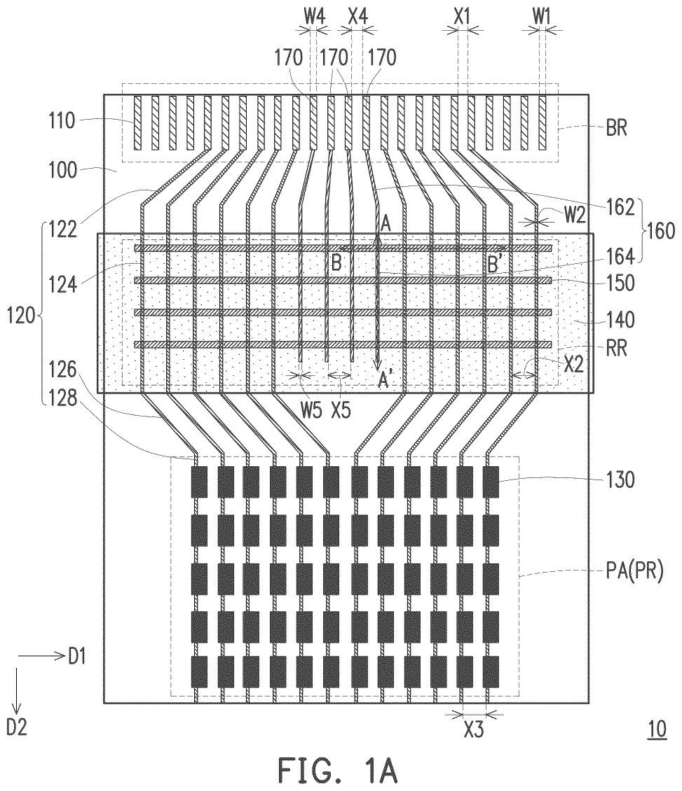

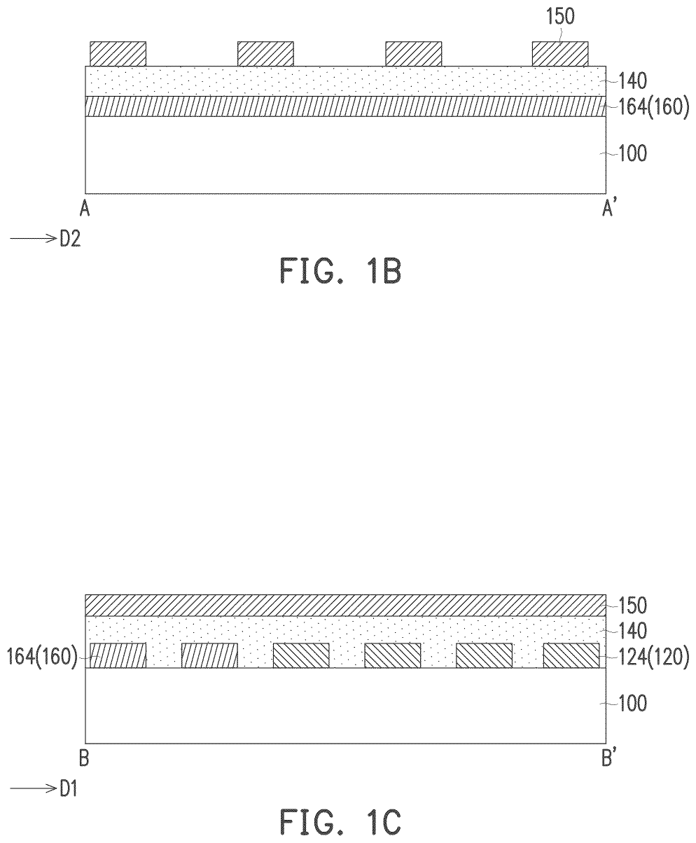

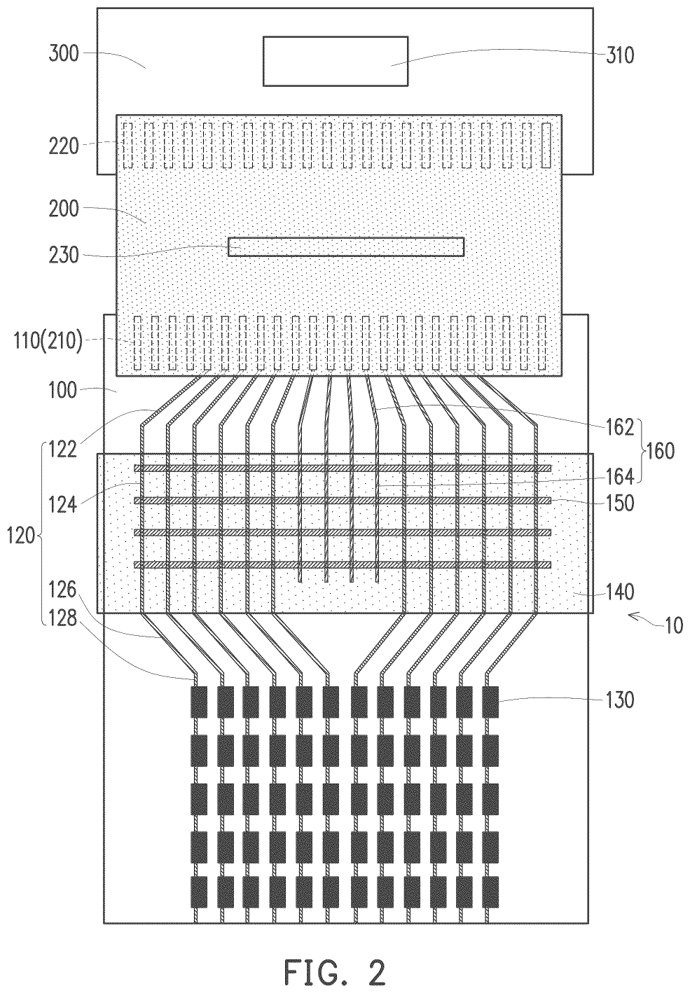

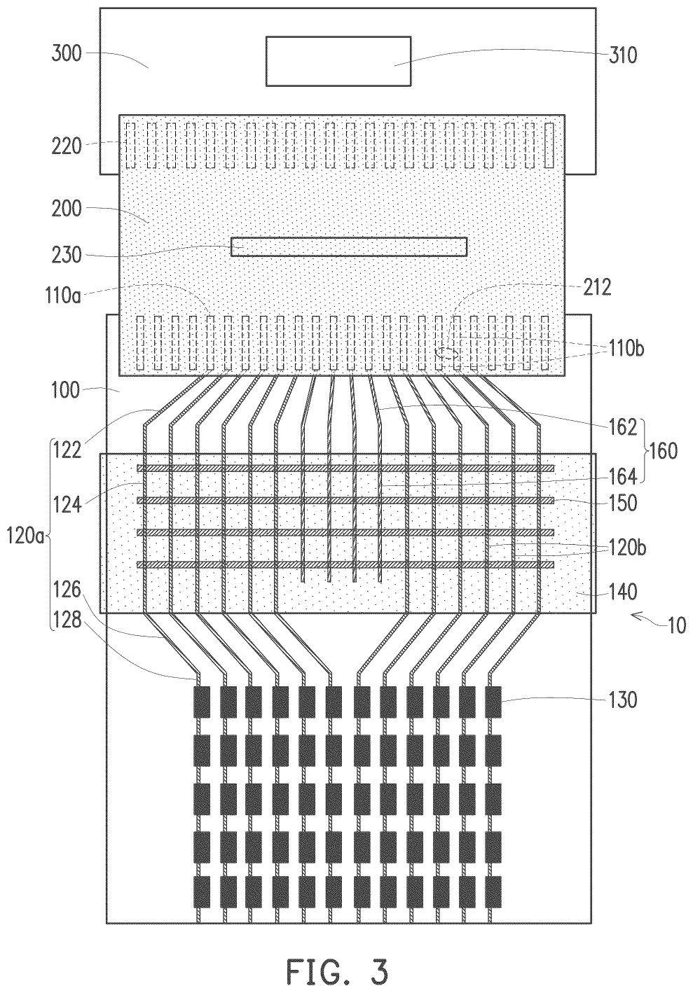

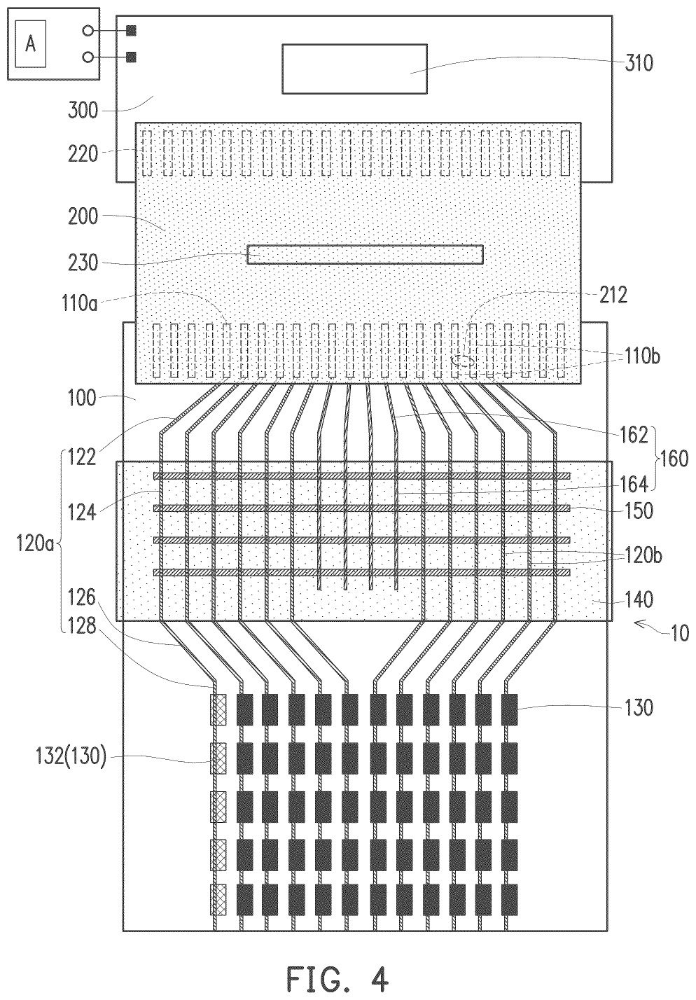

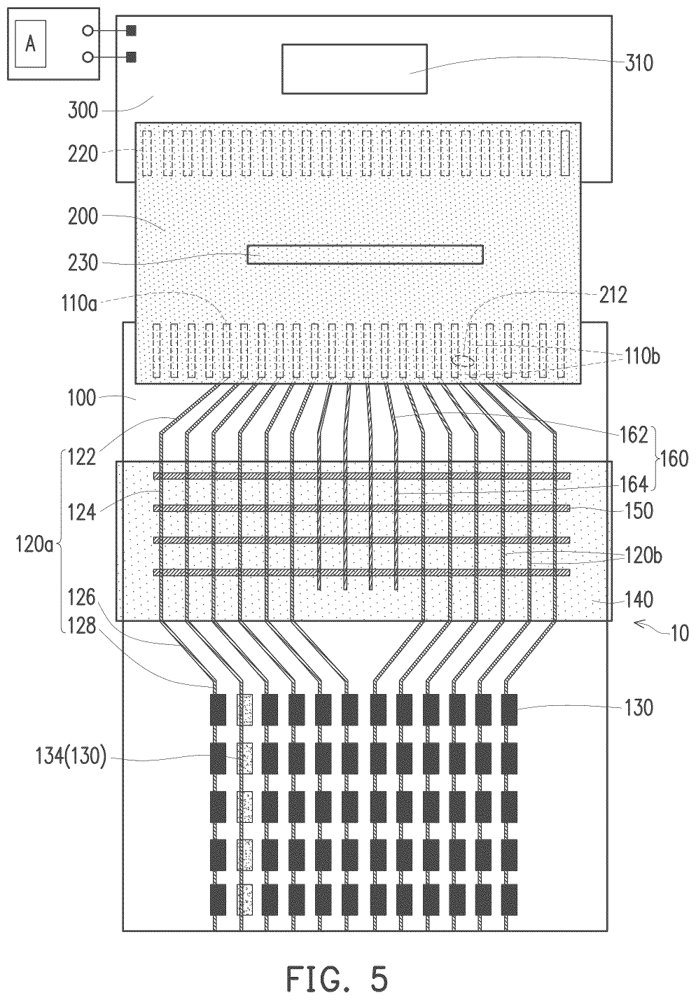

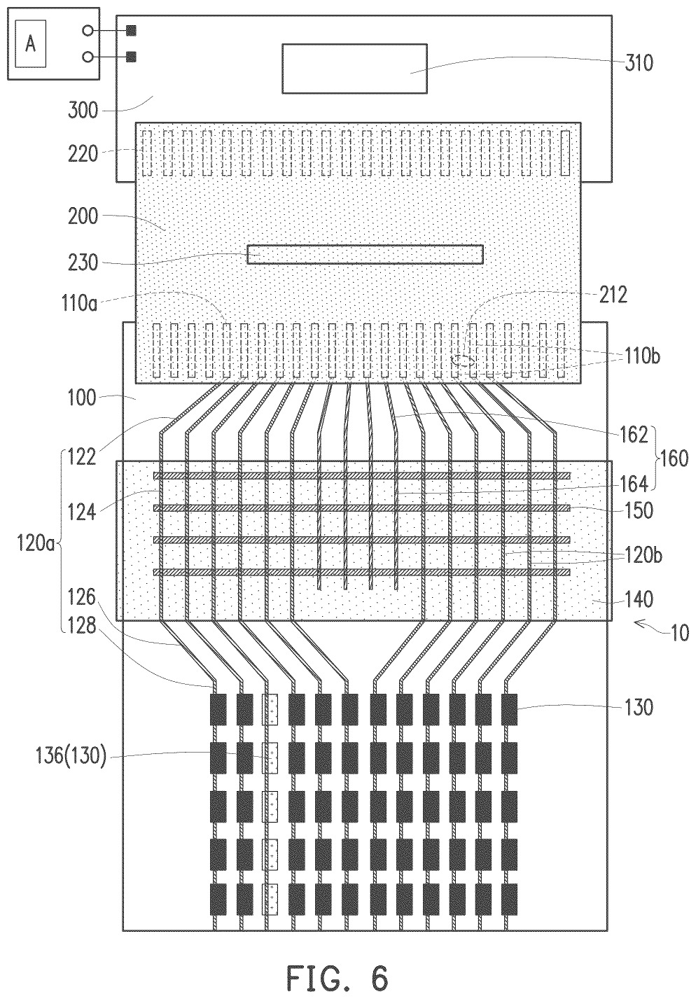

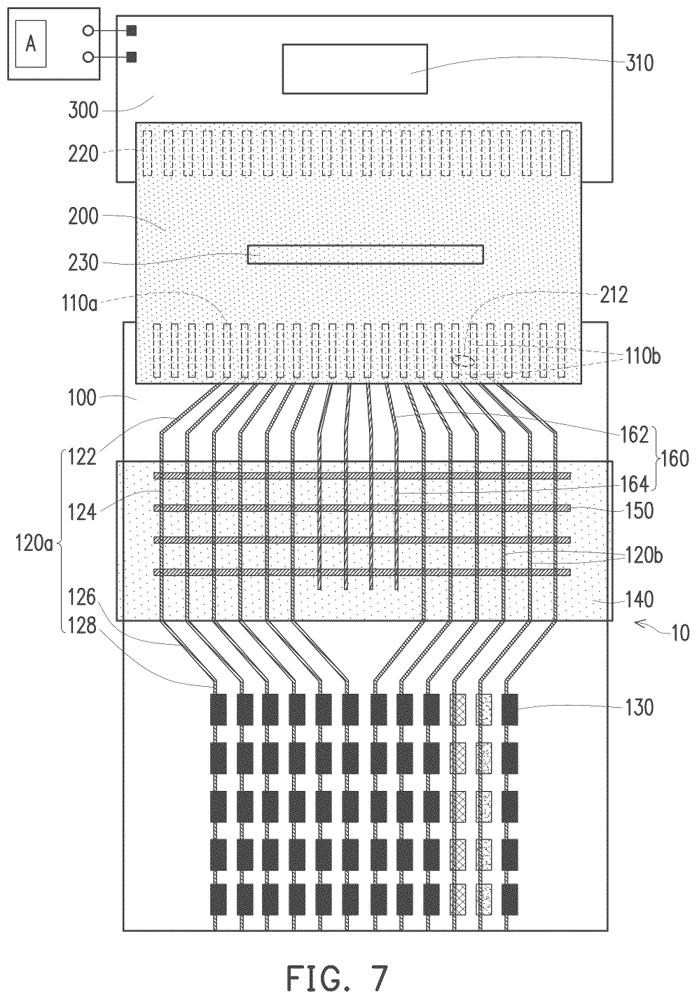

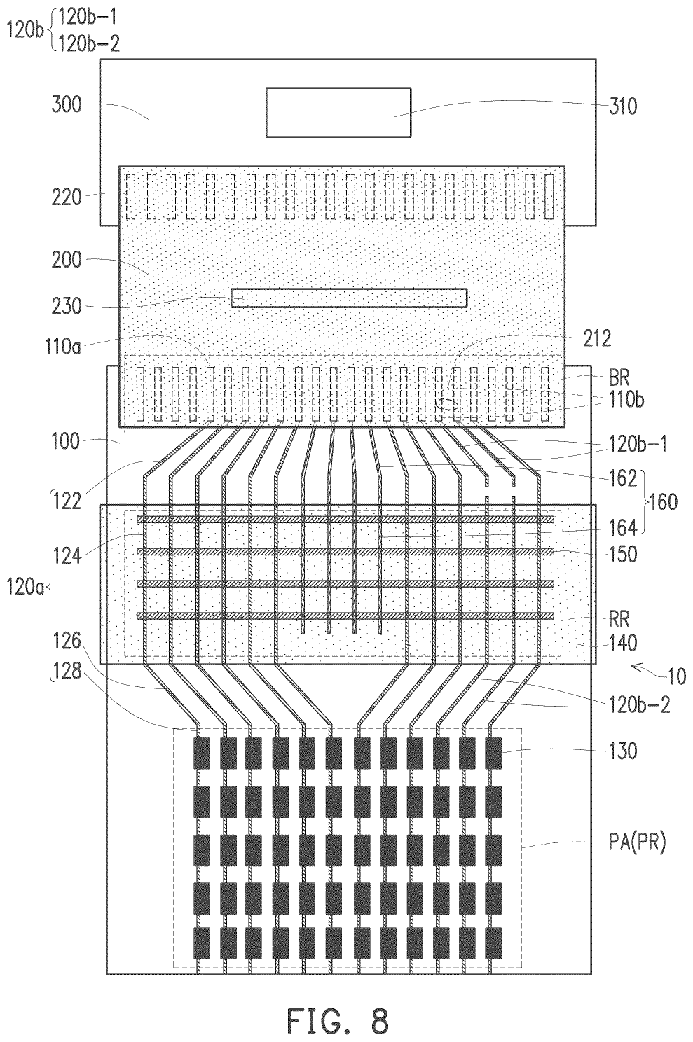

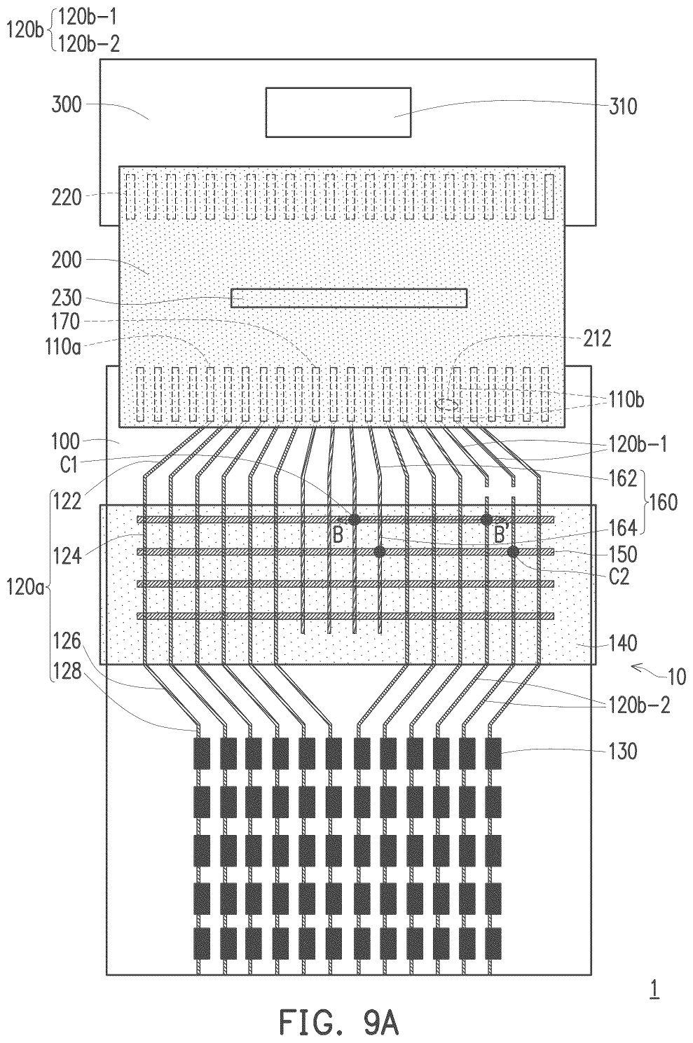

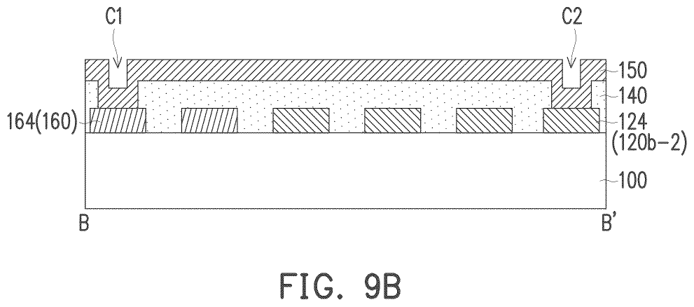

FIG. 1A, FIGS. 2 to 8, and FIG. 9A are top-view schematic diagrams of a fabrication method of a display panel 1 according to an embodiment of the disclosure. FIGS. 1B and 1C are cross-sectional schematic diagrams along Line A-A′ and Line B-B′ in FIG. 1A, respectively. FIG. 9B is a cross-sectional schematic diagram along Line B-B′in FIG. 9A. Referring to FIGS. 1A to 1C, a pixel array substrate 10 is provided. The pixel array substrate 10 includes a substrate 100, a pixel array PA, multiple bonding pads 110, multiple data lines 120, an isolation layer 140, multiple transfer lines 150, multiple repair signal lines 160, and multiple repair pads 170. In some embodiments, the pixel array substrate 10 further includes other signal lines, such as scan lines (not shown), shared signal lines (not shown), and the like, but the disclosure is not limited thereto.

The substrate 100 has a bonding pad area BR, a repair area RR, and a pixel array area PR. The repair area RR is located between the bonding pad area BR and the pixel array area PR. The substrate 100 may be a flexible substrate or a stretchable substrate. For example, materials of flexible substrates and stretchable substrates include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials. In other embodiments, the substrate 100 may also be a rigid substrate, the material of which may be glass, quartz, organic polymer, or opaque/reflective materials (e.g., conductive materials, metal, wafer, ceramic, or other adaptable materials), or other adaptable materials.

The bonding pads 110 and the repair pads 170 are located over the bonding pad area BR. The bonding pads 110 and the repair pads 170 are arranged in a row along a first direction D1, but the disclosure is not limited thereto. In other embodiments, the bonding pads 110 and the repair pads 170 may be arranged in two, three, four, or more rows.

Each of the bonding pad 110 and the repair pad 170 may have a single-layer structure or a multi-layer structure. For example, each of the bonding pad 110 and the repair pad 170 may be formed by multiple stacked conductive layers. The conductive layer includes, for example, a metal layer, metal oxide layer, metal nitride layer, or other suitable materials.

The pixel array PA is located over the pixel array area PR. In this embodiment, the pixel array PA includes multiple light-emitting elements 130 arranged in arrays along the first direction D1 and a second direction D2. The light-emitting element 130 is, for example, micro-light-emitting diode, organic light-emitting diode, or other suitable light-emitting elements. In some embodiments, the pixel array PA further includes multiple transistors, multiple passive elements (e.g., capacitors), and other electronic elements. The transistors and passive elements are configured with one another to construct a pixel control circuit (not shown). The switching and brightness of the light-emitting element 130 may be controlled through the pixel circuit.

The data lines 120 extend from the bonding pad area BR and, through the repair area RR, into the pixel array area PR. The data lines 120 electrically connect the bonding pads 110 to the pixel array PA, respectively. For example, each of the data lines 120 electrically connects a corresponding bonding pad 110 to multiple corresponding light-emitting elements 130. The data line 120 is electrically connected to the light-emitting element 130 through, for example, the pixel control circuit (not shown). In some embodiments, part of the bonding pads 110 may be dummy pads and not be connected to any of the data lines 120, but the disclosure is not limited thereto.

In some embodiments, each of the data lines 120 includes a first fan-out line segment 122, a repair area line segment 124, a second fan-out line segment 126, and a pixel array area line segment 128. The first fan-out line segment 122 is connected to the corresponding bonding pad 110 and extends from the bonding pad area BR to the repair area RR. The repair area line segment 124 is disposed over the repair area RR and connected between the first fan-out line segment 122 and the second fan-out line segment 126. The pixel array area line segment 128 is disposed over the pixel array area PR and electrically connected to the second fan-out line segment 126 and the light-emitting element 130.

In some embodiments, the disposition of the first fan-out line segment 122 enables a distance X2 between the adjacent repair area line segments 124 to be greater than a distance X1 between the adjacent bonding pads 110. In some embodiments, a width W1 of the bonding pad 110, the distance X1 between the adjacent bonding pads 110, a width W2 of the repair area line segment 124, and the distance X2 between the adjacent repair area line segments 124 may be adjusted according to the requirement.

In some embodiments, the disposition of the second fan-out line segment 126 enables a distance X3 between adjacent pixel array area line segments 128 to be less than or equal to the distance X2 between the adjacent repair area line segments 124.

In some embodiments, each of the data lines 120 may have a single-layer structure or a multi-layer structure. In some embodiments, the material of the data line 120 includes gold, silver, copper, aluminum, molybdenum, titanium, tantalum, other metals, or alloys of the aforementioned metals. In some embodiments, different line segments of the data line 120 may include the same or different conductive layers. Different conductive layers are separated by an insulating layer, and different conductive layers may be electrically connected to each other by penetrating through the conductive hole on the insulating layer.

The repair signal lines 160 extend from the bonding pad area BR into the repair area RR without extending into the pixel array area PR. In other words, an end of each of the repair signal lines 160 is located over the repair area RR. The repair signal lines 160 are electrically connected to the repair pads 170 respectively.

In some embodiments, each of the repair signal lines 160 includes a fan-out line segment 162 and a repair area line segment 164. The fan-out line segment 162 is connected to the corresponding repair pad 170 and extends from the bonding pad area BR to the repair area RR. The repair area line segment 164 is disposed over the repair area RR and connected to the corresponding fan-out line segment 162.

In some embodiments, the fan-out line segment 162 of the repair signal line 160 and the first fan-out line segment 122 of the data line 120 are arranged along the first direction D1. The fan-out line segments 162 are sandwiched between the first fan-out line segments 122. Similarly, the repair area line segment 164 of the repair signal line 160 and the repair area line segment 124 of the data line 120 are arranged along the first direction D1. The repair area line segments 164 are sandwiched between the repair area line segments 124. In some embodiments, the arrangement order of the repair signal lines 160 and the data lines 120 may be adjusted according to the requirement.

In some embodiments, the disposition of the fan-out line segment 162 enables a distance X5 between the adjacent repair area line segments 164 to be greater than a distance X4 between the adjacent repair pads 170. In some embodiments, a width W4 of the repair pad 170, the distance X4 between the adjacent repair pads 170, a width W5 of the repair area line segment 164, and the distance X5 between the adjacent repair area line segments 164 may be adjusted according to the requirement.

In some embodiments, each of the repair signal lines 160 may have a single-layer structure or a multi-layer structure. In some embodiments, the material of the repair signal line 160 includes gold, silver, copper, aluminum, molybdenum, titanium, tantalum, other metals, or alloys of the aforementioned metals. In some embodiments, different line segments of the repair signal line 160 may include the same or different conductive layers. Different conductive layers are separated by an insulating layer, and different conductive layers may be electrically connected to each other by penetrating through the conductive hole on the insulating layer.

The isolation layer 140 is disposed over the repair area RR and covers the repair area line segment 124 of the data line 120 and the repair area line segment 164 of the repair signal line 160. In some embodiments, the isolation layer 140 includes an organic insulating material or an inorganic insulating material.

Multiple transfer lines 150 are located over the repair area RR and arranged along the second direction D2. The isolation layer 140 is located between the transfer line 150 and the data line 120 and between the transfer line 150 and the repair signal line 160. At least part of the repair signal lines 160 and at least part of the data lines 120 are electrically insulated from the transfer line 150 due to the isolation layer 140. In this embodiment, the transfer line 150 is disposed on the isolation layer 140 and across the data line 120 and the repair signal line 160. For example, the transfer line 150 extends along the first direction D1 and overlaps the repair area line segments 124 of the multiple data lines 120 and the repair area line segments 164 of the multiple repair signal lines 160. On the other hand, the repair area line segments 124 of the multiple data lines 120 and the repair area line segments 164 of the multiple repair signal lines 160 extend, for example, along the second direction D2 that is different from the first direction D1. Each of the repair area line segments 124 and each of the repair area line segments 164 are arranged across the multiple transfer lines 150. In some embodiments, the first direction D1 is perpendicular to the second direction D2.

Referring to FIG. 2, a chip-on-film package structure 200 is bonded to the pixel array substrate 10. For example, multiple first pads 210 of the chip-on-film package structure 200 are bonded to the bonding pads 110 (referring to FIG. 1A) and the repair pads 170 (referring to FIG. 1A) of the pixel array substrate 10 respectively. In some embodiments, the chip-on-film package structure 200 is bonded to the pixel array substrate 10 through a heat-pressing process or other suitable processes. In some embodiments, a conductive adhesive, solder, or other suitable conductive connection materials are included between the chip-on-film package structure 200 and the pixel array substrate 10.

In some embodiments, the chip-on-film package structure 200 includes a driver chip 230. The driver chip 230 is electrically connected to the bonding pad 110 and the repair pad 170 through the first pad 210. In other words, a signal output from the driver chip 230 may be transmitted to the data line 120 and the repair signal line 160 through the bonding pad 110 and the repair pad 170 respectively.

A system board 300 is bonded to a second pad 220 of the chip-on-film package structure 200. In some embodiments, a timing controller chip (TCON) 310 is disposed on the system board 300 and electrically connected to the chip-on-film package structure 200 through the second pad 220. The TCON 310 is, for example, electrically connected to the driver chip 230 of the chip-on-film package structure 200. In other embodiments, the TCON 310 is disposed on the chip-on-film package structure 200.

In some embodiments, when the chip-on-film package structure 200 is bonded to the pixel array substrate 10, a contaminant 212 might occur due to process errors or other factors, resulting in the need for a rework process. For example, the first time the chip-on-film package structure 200 is bonded to the pixel array substrate 10, the chip-on-film package structure 200 might not be properly bonded to the pixel array substrate 10 due to inaccurate alignment (or the contaminant 212 occurs due to other factors). Where the substrate 100 is a rigid substrate, the chip-on-film package structure 200 may be separated from the pixel array substrate 10 before performing the process of bonding the chip-on-film package structure 200 to the pixel array substrate 10 again. However, where the substrate 100 is a flexible substrate or a stretchable substrate, the separation operation cannot be performed again as the first bonding pad 110 might become invalid and peel off during the separation of the chip-on-film package structure 200 and the pixel array substrate 10.

However, the rework process might result in contamination or damage to the pixel array substrate 10, and especially to a position close to where the chip-on-film package structure 200 and the pixel array substrate 10 are bonded. For example, where the substrate 100 is a rigid substrate, the contaminant 212 might not be cleaned. For another example, where the substrate 100 is a flexible substrate or a stretchable substrate, the contaminant 212 occurs when the chip-on-film package structure 200 is first bonded to the pixel array substrate 10. For example, as shown in FIG. 3, the contaminant 212 occurs at a position where the chip-on-film package structure 200 and the pixel array substrate 10 are bonded, and the contaminant 212 or the like easily results in abnormal signals and affects a displayed image.

For example, after the contaminant 212 is formed, part of the data lines 120 malfunction. To facilitate distinguishing between the properly functioning data line 120 and the malfunctioning data line 120, a first data line 120a represents the properly functioning data line 120 and a second data line 120b represents the malfunctioning data line 120 hereafter. A first bonding pad 110a represents the bonding pad 110 bonded to the first data line 120a, and a second bonding pad 110b represents the bonding pad 110 bonded to the second data line 120b. In this embodiment, two adjacent second data lines 120b are short-circuited to each other due to the contaminant 212.

The quantity and distribution positions of the first data line 120a, the first bonding pad 110a, the second data line 120b, and the second bonding pad 110b may be different depending on the damage condition of the pixel array substrate 10, and are not limited to the conditions shown in FIG. 3. In this embodiment, the repair pad 170 is located between the first bonding pads 110a.

A repair process needs to be performed on the pixel array substrate 10 to solve the problem of the malfunctioning second data line 120b. First, a detection procedure is performed on the pixel array substrate 10 to determine the position of the second data line 120b. As shown in FIGS. 4 to 6, current signals are provided to different data lines respectively. The corresponding light-emitting elements 130 are detected to see if the light-emitting elements 130 function properly. In this embodiment, the light-emitting element 130 includes a first color light-emitting element 132, a second color light-emitting element 134, and a third color light-emitting element 136. Each of the data lines corresponds to a light-emitting element 130 of the same color. In some embodiments, the first color light-emitting element 132, the second color light-emitting element 134, and the third color light-emitting element 136 are a red light-emitting element, a green light-emitting element, and a blue light-emitting element respectively.

After the detection procedure is performed, an open circuit or a short circuit of the second data line 120b is detected. In this embodiment, the two second data lines 120b are detected to have abnormal currents resulted from a short circuit, as shown in FIG. 7.

Next, referring to FIG. 8, a cutting process is performed to cut the second data line 120b into a first line segment 120b-1 and a second line segment 120b-2 separated from each other. The first line segment 120b-1 is electrically connected to the second bonding pad 110b, and the second line segment 120b-2 is electrically connected to the pixel array PA. In some embodiments, a method of performing the cutting process includes a laser cutting process. In some embodiments, a distance (i.e., a cutting width) between the first line segment 120b-1 and the second line segment 120b-2 may be adjusted according to the requirement.

A position where the first line segment 120b-1 and the second line segment 120b-2 are separated is located between the bonding pad area BR and the repair area RR. In other words, the second data line 120b is cut between the bonding pad area BR and the repair area RR.

In some embodiments, the first line segment 120b-1 includes the first fan-out line segment 122 and a part of the repair area line segment 124 while the second line segment 120b-2 includes the other part of the repair area line segment 124, the second fan-out line segment 126, and the pixel array area line segment 128. In other words, the repair area line segment 124 is cut. In other embodiments, the first fan-out line segment 122 may also be cut so as to include a part of the first fan-out line segment 122 in the first line segment 120b-1 and include the other part of the first fan-out line segment 122, the repair area line segment 124, the second fan-out line segment 126, and the pixel array area line segment 128 in the second line segment 120b-2.

In some embodiments, any of the detection steps shown in FIGS. 4 to 6 may be performed again to determine that the cutting process is correctly performed.

Referring to FIGS. 9A and 9B, a welding process is performed to form one or more first connection points C1 and one or more second connection points C2 in the isolation layer 140. The repair area line segment 164 of the repair signal line 160 is electrically connected to the corresponding transfer line 150 through the corresponding first connection point C1, and the transfer line 150 is electrically connected to the repair area line segment 124 in the second line segment 120b-2 of the corresponding second data line 120b through the corresponding second connection point C2. In some embodiments, a method of performing the welding process includes a laser welding process.

Through the repair process, a signal may be provided to the second line segment 120b-2 of the second data line 120b through the repair pad 170, the repair signal line 160, and the transfer line 150, further enabling the proper functioning of the light-emitting element 130 corresponding to the pixel array area line segment 128 of the second data line 120b.

FIG. 10 is a top-view schematic diagram of a display panel 2 according to another embodiment of the disclosure. It must be noted that the embodiment of FIG. 10 adopts the reference numbers and part of the content in the embodiments of FIGS. 1A to 9B, where identical or similar reference numbers are used to indicate identical or similar components, and repeated description for the same technical contents is omitted. For the description of the omitted parts, reference may be made to the foregoing embodiments, which will not be repeated herein.

The main difference between the display panel 2 in FIG. 10 and the display panel 1 in FIG. 9A is that the malfunctioning second data line 120b in the display panel 2 in FIG. 10 does not result from a contaminant. In the display panel 2, the second data line 120b malfunctions due to disconnection. For example, where the substrate 100 is a rigid substrate, if the second data line 120b is damaged when the chip-on-film package structure 200 is removed during the rework process of bonding the chip-on-film package structure 200 to the pixel array substrate 10, the first fan-out line segment 122 of the second data line 120b is disconnected. Where the substrate 100 is a flexible substrate or a stretchable substrate, the second data line 120b malfunctions due to disconnection when the chip-on-film package structure 200 is first bonded to the pixel array substrate 10.

In this embodiment, an additional cutting process as shown in FIG. 8 is not needed for the second data line 120b. Specifically, the detection procedure as shown in FIGS. 4 to 7 is utilized to determine the position of the second data line 120b and detect that the second data line 120b has an abnormal current resulted from an open circuit. Then, the welding process is directly performed to form the first connection point C1 and the second connection point C2 in the isolation layer 140 so as to repair the second data line 120b.

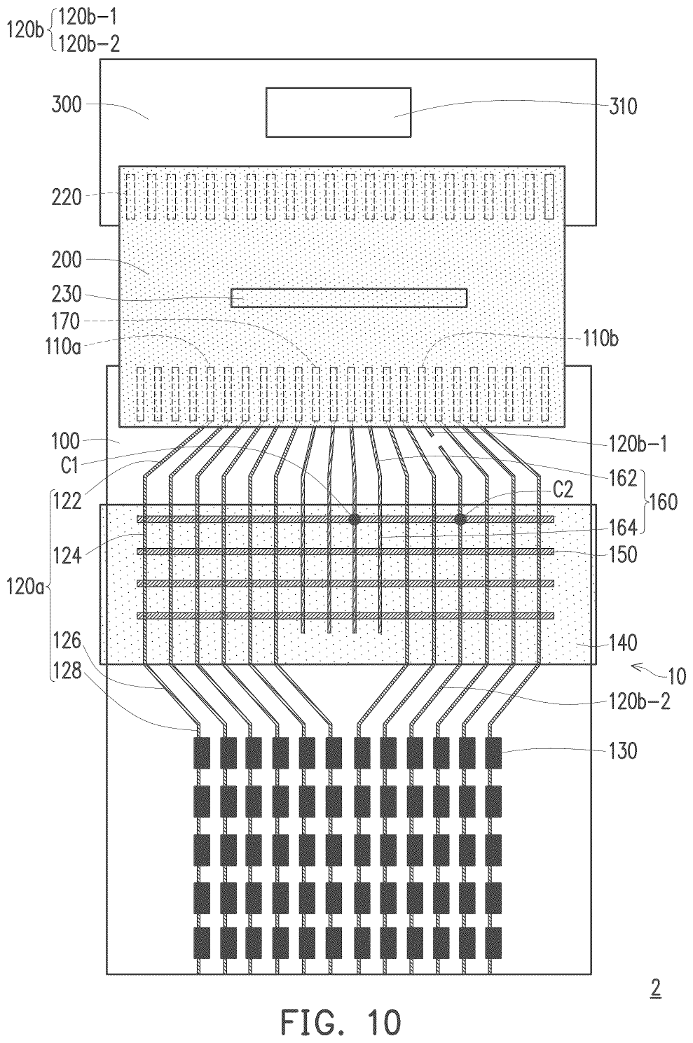

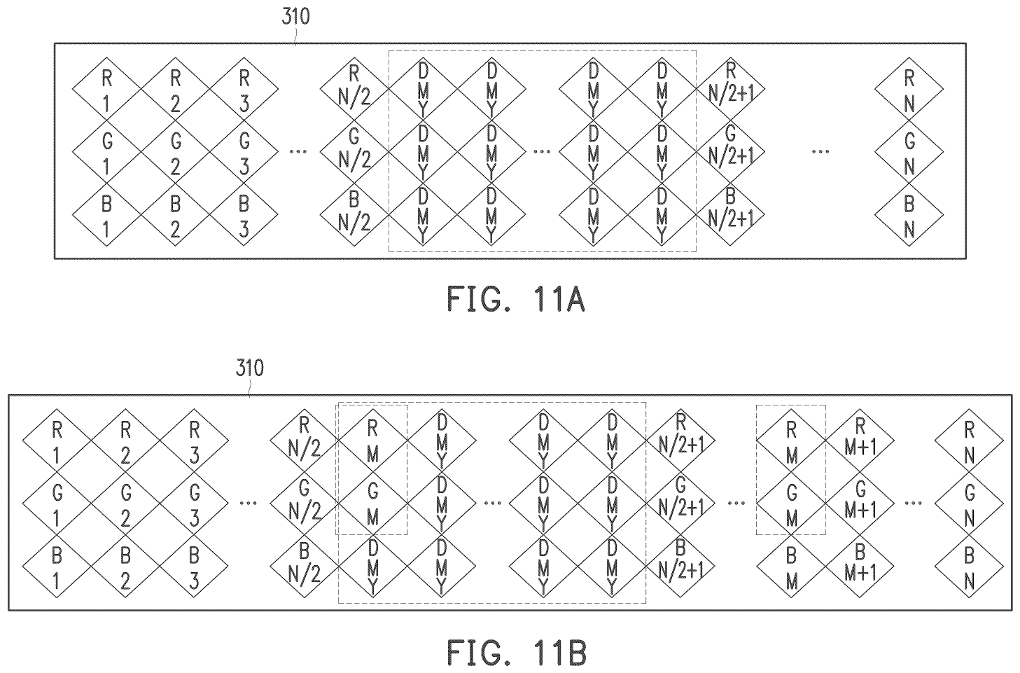

FIGS. 11A and 11B are schematic diagrams of an arrangement of a digital signal protocol of a timing controller chip (TCON) 310 according to an embodiment of the disclosure. Referring to FIG. 11A, the TCON 310 has multiple signal output terminals R1 to RN, G1 to GN, and B1 to BN, wherein N is a positive integer. Referring to FIGS. 2 and 11A at the same time, the output terminals R1 to RN, G1 to GN, and B1 to BN are used to provide data line signals to the corresponding data lines 120. For example, the output terminal R1 provides a signal to a data line 120 corresponding to a red subpixel in a first row. The output terminal G1 provides a signal to a data line 120 corresponding to a green subpixel in the first row. The output terminal B1 provides a signal to a data line 120 corresponding to a blue subpixel in the first row. The output terminal R2 provides a signal to a data line 120 corresponding to a red subpixel in a second row. The rest is deduced by analogy.

In some embodiments, the data line signal provided by the TCON 310 is a digital signal. Such a digital signal may be converted into an analog signal and then transmitted to the corresponding data line through the driver chip 230 of the chip-on-film package structure 200.

In this embodiment, the TCON 310 further includes repair terminals DMY. Before the repair process is performed on the display panel, the repair terminals DMY do not provide any signal, which is to say, the repair terminals DMY are floating at this time.

After the display panel is identified as malfunctioning, the repair process is performed on the display panel. Next, the signal output from the TCON 310 is adjusted. For example, referring to FIGS. 9A and 11B, two second data lines 120b malfunction. Through the detection procedure, it is identified that the two second data lines 120b were originally provided with signals from output terminals RM and GM respectively, wherein M is a positive integer between 1 and N.

After the repair process is performed, two of the repair terminals DMY provide the same data line signals as the output terminals RM and GM instead. The data line signals are converted by the driver chip 230 and then transmitted to the corresponding repair pad 170. Next, the data line signals are transmitted to the second line segments 120b-2 of the repaired second data lines 120b through the repair signal line 160 and the transfer line 150. At the same time, the other repair terminals DMY still do not provide any signal to the other repair signal lines 160 that are not used in the repair process. In other words, after the repair process is performed, two of the repair terminals DMY provide the same data line signals as the output terminals RM and GM instead to the repair signal line 160 underwent the repair process while the other repair signal lines 160 remain in a floating state.

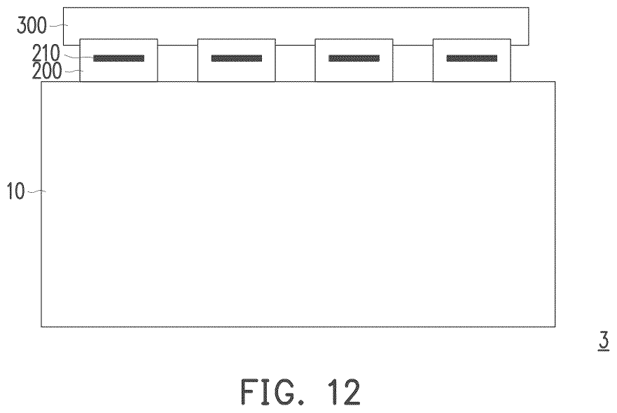

FIG. 12 is a top-view schematic diagram of a display panel 3 according to still another embodiment of the disclosure. In a display panel 3 in FIG. 12, multiple chip-on-film package structures 200 are connected to a pixel array substrate 10. References can be made to the embodiments of FIGS. 1A to 9B for the specific structure of the pixel array substrate 10, which will not be repeated herein.

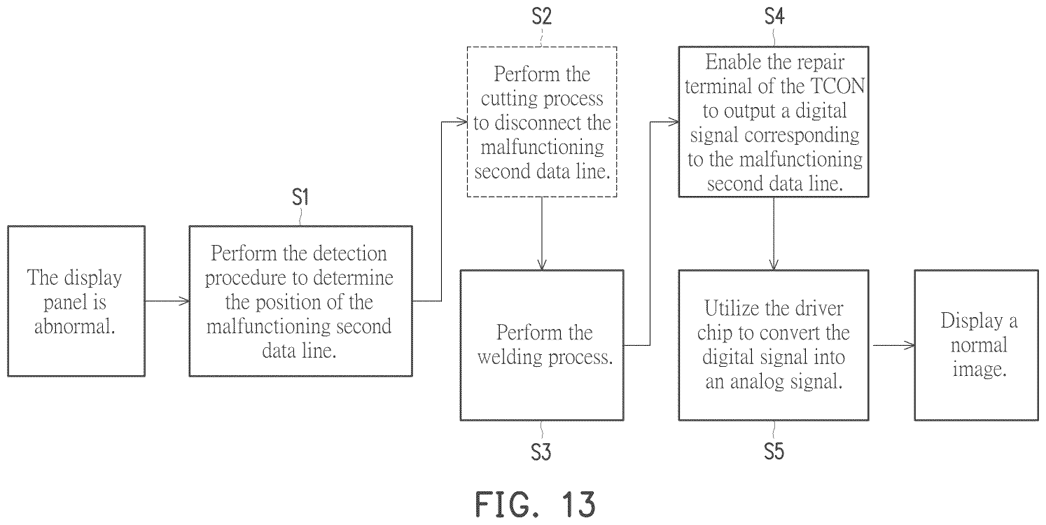

FIG. 13 is a flowchart of a fabrication method of a display panel in an embodiment. Referring to Step S1 in FIG. 13 and FIGS. 5 to 7, after the display panel is identified to be abnormal, the detection procedure is performed to determine the position of the malfunctioning second data line.

Referring to Step S2 in FIG. 13 and FIG. 8, the cutting process may be performed to disconnect the malfunctioning second data line. In other embodiments, Step S2 may be omitted if the malfunctioning second data line results from an open circuit.

Referring to Step S3 in FIG. 13 and FIG. 9, the welding process is performed to repair the second data line by utilizing the repair signal line and the transfer line.

Referring to Step S4 in FIG. 13 and FIGS. 9 and 11B, the repair terminal DMY of the TCON 310 is enabled to output a digital signal corresponding to the malfunctioning second data line. Referring to Step S5 in FIG. 13 and FIGS. 9 and 11B, the driver chip is utilized to convert the digital signal into an analog signal. In this way, the repair process for the display panel is completed, enabling the display panel to display a normal image.

What is claimed is:

1. A display panel, comprising:
a substrate, having a bonding pad area, a repair area, and a pixel array area, wherein the repair area is located between the bonding pad area and the pixel array area;
a plurality of first bonding pads and a plurality of repair pads, located over the bonding pad area;
a pixel array, located over the pixel array area;
a plurality of first data lines, extending from the bonding pad area to the pixel array area, wherein the plurality of first data lines electrically connect the plurality of first bonding pads to the pixel array respectively;
a plurality of transfer lines, located over the repair area and across the plurality of first data lines;
a plurality of repair signal lines, extending from the bonding pad area to the repair area and electrically connected to the plurality of repair pads respectively, wherein an end of each of the plurality of repair signal lines is located over the repair area; and
an isolation layer, located between the plurality of transfer lines and the plurality of repair signal lines.

2. The display panel of claim 1, wherein at least a part of the plurality of repair signal lines is electrically insulated from the plurality of transfer lines due to the isolation layer.

3. The display panel of claim 1, further comprising:
a second data line, extending from the bonding pad area to the pixel array area and comprising a first line segment and a second line segment separated from each other, wherein the second line segment is electrically connected to the pixel array, wherein one of the plurality of repair signal lines is electrically connected to one of the plurality of transfer lines through a first connection point located in the isolation layer, and the one of the plurality of transfer lines is electrically connected to the second line segment through a second connection point located in the isolation layer.

4. The display panel of claim 3, wherein a position where the first line segment and the second line segment are separated is located between the bonding pad area and the repair area.

5. The display panel of claim 3, further comprising:
a second bonding pad, located over the bonding pad area, wherein the first line segment is electrically connected to the second bonding pad.

6. The display panel of claim 1, wherein the plurality of repair pads are located between the plurality of first bonding pads.

7. The display panel of claim 1, further comprising:
a chip-on-film package structure, bonded to the plurality of first bonding pads and the plurality of repair pads.

8. A fabrication method of a display panel, comprising:
providing a pixel array substrate, the pixel array substrate comprising:
a substrate, having a bonding pad area, a repair area, and a pixel array area, wherein the repair area is located between the bonding pad area and the pixel array area;
a plurality of first bonding pads and a plurality of repair pads, located over the bonding pad area;
a second bonding pad, located over the bonding pad area;
a pixel array, located over the pixel array area;
a plurality of first data lines, extending from the bonding pad area to the pixel array area, wherein the plurality of first data lines electrically connect the plurality of first bonding pads to the pixel array respectively;
a second data line, extending from the bonding pad area to the pixel array area;
a plurality of transfer lines, located over the repair area and across the plurality of first data lines and the second data line;
a plurality of repair signal lines, extending from the bonding pad area to the repair area and electrically connected to the plurality of repair pads respectively, wherein an end of each of the plurality of repair signal lines is located over the repair area; and
an isolation layer, located between the plurality of transfer lines and the plurality of repair signal lines;
performing a detection procedure on the pixel array substrate to detect an open circuit or a short circuit of the second data line; and
performing a welding process to form a first connection point and a second connection point in the isolation layer, wherein one of the plurality of repair signal lines is electrically connected to one of the plurality of transfer lines through the first connection point, and the one of the plurality of transfer lines is electrically connected to a part of the second data line through the second connection point.

9. The fabrication method of claim 8, further comprising:
performing a cutting process to cut the second data line into a first line segment and a second line segment separated from each other, wherein the first line segment is electrically connected to the second bonding pad, and the second line segment is electrically connected to the pixel array and the second connection point.

10. The fabrication method of claim 8, further comprising:
providing a data line signal for the one of the plurality of repair signal lines, wherein another one of the plurality of repair signal lines is floating.
